(19) United States
(12) Patent Application Publication
(10) Pub. No.: US 2025/0220819 A1
(43) Pub. Date: Jul. 3, 2025

(54) COMPONENT EMBEDDED IN MOLD MATERIAL FOR MITIGATING THICKNESS MISMATCH WITH CORE

(71) Applicant: Intel Corporation, Santa Clara, CA (US)

(72) Inventors: Pratyasha MOHAPATRA, Hillsboro, OR (US); Soham AGARWAL, Chandler, AZ (US); Pratyush MISHRA, Tempe, AZ (US); Benjamin DUONG, Phoenix, AZ (US); Kari HERNANDEZ, Phoenix, AZ (US)

(21) Appl. No.: 18/398,815

(22) Filed: Dec. 28, 2023

(51) Int. Cl. H05K 1/18; H01L 21/48; H01L 23/00; H01L 23/498; H01L 25/16

(52) U.S. Cl. CPC H05K 1/186; H01L 21/486; H01L 23/49827; H01L 25/16; H01L 24/16; H01L 2224/16225; H05K 2201/10015; H05K 2201/10022; H05K 2201/1003; H05K 2201/10522; H05K 2201/10568

(57) ABSTRACT

Embodiments disclosed herein include passive electrical components with thickness modifications in order to improve embedding processes. In an embodiment, such an apparatus comprises a substrate with a first width, where the substrate comprises a first surface, a second surface opposite from the first surface, and sidewall surfaces coupling the first surface to the second surface. In an embodiment, a layer with a second width that is greater than the first width contacts the substrate and covers the sidewall surfaces and the first surface of the substrate.

### BACKGROUND

As advanced packaging is enabling more aggressive computation capability, high power and high quality power delivery is needed to support all of the overlying chiplets. Accordingly, the ability to embed passive components (e.g., capacitors, inductors, resistors, etc.) into the package substrate will enable improved performance compared to placing the passive components on the land side of the package. Embedding components in the core is beneficial because there is less routing in the core compared to overlying and underlying buildup layers. As such, space within the package substrate is more fully utilized.

However, substrate core thickness is defined by the total package thermomechanical stress level. This required thickness can be significantly different than the thickness of the passive component. For example, in the case of a deep trench capacitor (DTC), the DTC is fabricated on a silicon wafer. The wafer will have a thickness that is potentially hundreds of microns different than the thickness of the core, which can be approximately 1.0 mm or greater. Placing such passive components in deep cavities through the core can be problematic. For example, the passive components may shift or rotate during embedding.

### BRIEF DESCRIPTION OF THE DRAWINGS

FIG. 1 is a cross-sectional illustration of a core with an embedded passive component that has shifted during the embedding process, in accordance with an embodiment.

FIG. 2A is a cross-sectional illustration of a device with a substrate that is embedded in a mold layer, in accordance with an embodiment.

FIG. 2B is a cross-sectional illustration of a device with a first substrate and a second substrate embedded in a mold layer, in accordance with an embodiment.

FIG. 2C is a cross-sectional illustration of a device with a first substrate with a first thickness and a second substrate with a second thickness embedded in a mold layer, in accordance with an embodiment.

FIGS. 3A-3C are cross-sectional illustrations depicting a process for forming a device with a substrate embedded in a mold layer, in accordance with an embodiment.

FIGS. 4A-4C are cross-sectional illustrations depicting a process for forming a device from a reconstituted substrate, in accordance with an embodiment.

FIG. 4D is a process flow diagram depicting a process for forming a plurality of devices from a reconstitution process, in accordance with an embodiment.

FIGS. 5A-5F are cross-sectional illustrations depicting a process for forming a substrate with an embedded device that includes a mold layer around a substrate, in accordance with an embodiment.

FIG. 6A is a cross-sectional illustration of a portion of a package substrate with a pair of devices embedded in a single cavity, in accordance with an embodiment.

FIG. 6B is a cross-sectional illustration of a portion of a package substrate with a pair of devices with substrates that have different thicknesses embedded in a single cavity, in accordance with an embodiment.

FIG. 7A is a cross-sectional illustration of a portion of a package substrate with a pair of cavities that each comprise a device, in accordance with an embodiment.

FIG. 7B is a cross-sectional illustration of a portion of a package substrate with a pair of cavities that comprise devices with substrates that have different thicknesses, in accordance with an embodiment.

FIG. 8 is a cross-sectional illustration of an electronic system with a package substrate that includes an embedded component with a mold layer around a substrate, in accordance with an embodiment.

FIG. 9 is a schematic of a computing device built in accordance with an embodiment.

### EMBODIMENTS OF THE PRESENT DISCLOSURE

Described herein are electronic systems, and more particularly, devices with a substrate embedded in a mold layer and placed in a cavity through a core of a package substrate, in accordance with various embodiments. In the following description, various aspects of the illustrative implementations will be described using terms commonly employed by those skilled in the art to convey the substance of their work to others skilled in the art. However, it will be apparent to those skilled in the art that the present disclosure may be practiced with only some of the described aspects. For purposes of explanation, specific numbers, materials and configurations are set forth in order to provide a thorough understanding of the illustrative implementations. However, it will be apparent to one skilled in the art that the present disclosure may be practiced without the specific details. In other instances, well-known features are omitted or simplified in order not to obscure the illustrative implementations.

Various operations will be described as multiple discrete operations, in turn, in a manner that is most helpful in understanding the present disclosure, however, the order of description should not be construed to imply that these operations are necessarily order dependent. In particular, these operations need not be performed in the order of presentation.

Various embodiments or aspects of the disclosure are described herein. In some implementations, the different embodiments are practiced separately. However, embodiments are not limited to embodiments being practiced in isolation. For example, two or more different embodiments can be combined together in order to be practiced as a single device, process, structure, or the like. The entirety of various embodiments can be combined together in some instances. In other instances, portions of a first embodiment can be combined with portions of one or more different embodiments. For example, a portion of a first embodiment can be combined with a portion of a second embodiment, or a portion of a first embodiment can be combined with a portion of a second embodiment and a portion of a third embodiment.

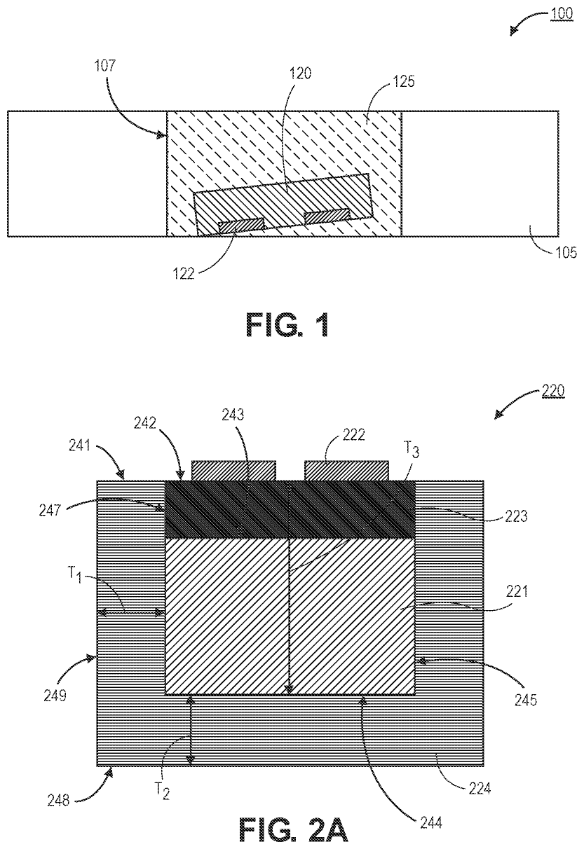

As noted above, introducing passive components (e.g., inductors, capacitors, resistors, etc.) into the package substrate is desirable to improve power delivery and performance for the overlying chiplets compared to placing the passive components on the land side of the package substrate. This is due, at least in part, to the passive components being physically closer to the chiplets when they are integrated into the package substrate. One suitable location in the package substrate for the passive components is the core. The core has underutilized space that can be leveraged to house the passive components. However, the thickness of the passive components is usually smaller than a thickness of the core. This can lead to integration and manufacturing issues. Examples of these drawbacks can be seen in FIG. 1.

Referring now to FIG. 1, a cross-sectional illustration of a portion of a package substrate 100 is shown, in accordance with an embodiment. The package substrate 100 may comprise a core 105. The core 105 may sometimes be referred to simply as a substrate. The core 105 may be a glass core, an organic core, or the like. In an embodiment, a cavity 107 passes at least partially through the core 105. For example, in FIG. 1 the cavity 107 passes entirely through the core 105.

In an embodiment, a component 120 is provided in the cavity 107. The component 120 may have a thickness that is smaller than a thickness of the core 105. For example, the component 120 may have a thickness that is hundreds of microns thinner than the core 105. The component 120 is secured within the cavity 107 through the use of a fill layer 125. The fill layer 125 may be a dielectric material, such as a mold layer, an epoxy, an adhesive, or the like. However, during the filling process, the component 120 may shift and/or rotate. The movement of the component 120 may be due, at least in part, to the introduction of pressure to the component 120 during the filling process. As shown, the component 120 has tilted so that one side is raised up from the bottom of the core 105. This may make it difficult to make electrical contact to the pads 122 that are at the bottom of the component 120 in subsequent processing operations.

Accordingly, embodiments disclosed herein reduce movement of the electrically passive component by providing a device that comprises a component that is at least partially embedded in a mold layer. The mold layer provides additional thickness to the device in order to substantially match the thickness of the core. The mold layer may be provided on multiple surfaces of the electrically passive component. For example, the mold layer may be provided over a bottom surface of the electrically passive component and along sidewalls of the electrically passive component. In an embodiment, a top surface of the electrically passive component is substantially coplanar with a top surface of the mold layer. That is, the top surface of the electrically passive component remains exposed in order to allow for electrical connection to the electrically passive component.

In an embodiment, the device may be formed through multiple different process flows. In one embodiment, each electrically passive component is overmolded with a molding material. In other embodiments, a plurality of electrically passive components can be overmolded together to form a reconstituted substrate. The electrically passive components can then be singulated into individual devices.

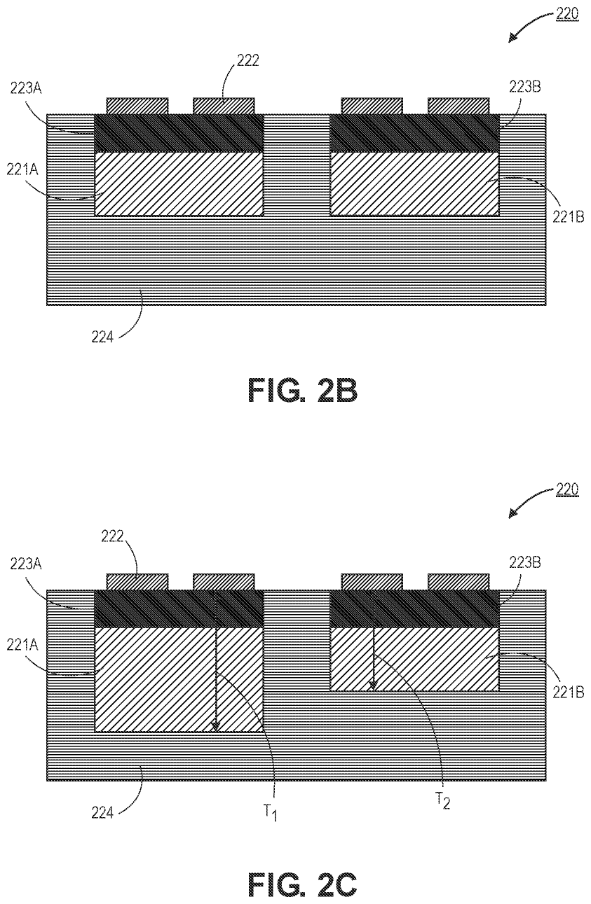

Referring now to FIG. 2A, a cross-sectional illustration of a device 220 is shown, in accordance with an embodiment. In an embodiment, the device 220 may comprise an electrically passive component. That is, the device 220 may include one or more of an inductor, a capacitor, a resistor, or the like. In a particular embodiment, the component 220 may be a deep trench capacitor (DTC). For example, the electrically passive component may be integrated into and/or part of a substrate 221. Routing layer 223 may also be provided over a surface 243 of the substrate 221 in some embodiments. In the Figures described herein, the substrate 221 and the routing layer 223 are shown as simple layers. The electrical routing (e.g., traces, pads, plates, electrodes), insulators, dielectrics (e.g., high-k dielectrics for capacitors), magnetic material (e.g., for inductors), and/or the like are omitted for simplicity. However, it is to be appreciated that device 220 may include any structures that enable functionality of various passive components.

In an embodiment, the substrate 221 may include any suitable material that provides a solid base on which (or into which) passive structures can be fabricated. In some embodiments, the substrate 221 may comprise a semiconductor material, such as silicon. For example, a silicon wafer may be processed to produce a plurality of passive devices. After processing, the silicon wafer is singulated in order to provide individual substrates 221. While silicon can be used in some embodiments, other embodiments may include a substrate 221 that comprises a ceramic, a glass, an insulator, or the like.

In an embodiment, the routing layer 223 may be a different material than the substrate 221. For example, the routing layer 223 may include a dielectric material, such as one comprising silicon and oxygen (e.g., SiO₂) or silicon and nitrogen (e.g., Si₃N₄). Organic dielectrics may also be used in some embodiments. The routing layer 223 may include electrical routing (not shown), such as pads, traces, and/or the like. In some embodiments, the routing layer 223 is omitted, or the electrical routing is otherwise provided in and/or on the substrate 221.

In an embodiment, a layer 224 is provided around the substrate 221 and/or the routing layer 223. The layer 224 may be a molding material, such as, but not limited to, an epoxy, an organic dielectric material, or the like. In some embodiments, filler particles (not shown) may be dispersed within the layer 224. Filler particles may be used in order to modify a coefficient of thermal expansion (CTE) of the layer 224 in order to more closely match the CTE of the substrate 221 and/or the routing layer 223. Matching CTEs may reduce stress and provide enhanced reliability.

In an embodiment, the layer 224 may contact a first surface 244 of the substrate 221 and sidewall surfaces 245 of the substrate 221. The layer 224 may also contact a sidewall 247 of the routing layer 223. In an embodiment, a top surface 241 of the layer 224 may be substantially coplanar with a surface 242 of the routing layer 223 (or with a surface 243 of the substrate 221 when the routing layer 223 is omitted). As used herein, “substantially coplanar” may refer to two surfaces that are within 10 μm of being coplanar with each other.

In an embodiment, the layer 224 may have a first thickness T₁ between sidewall 245 of the substrate 221 and sidewall 249 of the layer 224. The layer 224 may have a second thickness T₂ between the bottom surface 244 of the substrate 221 and the bottom surface 248 of the layer 224. In an embodiment, the second thickness T₂ may be greater than the first thickness T₁. A total thickness of the device 220 between the bottom surface 248 of the layer 224 and the top surface 241 of the layer 224 may be approximately 500 μm or greater, approximately 1.0 mm or greater, or approximately 1.5 mm or greater. Though, thinner thicknesses for the device 220 may also be used in some embodiments. In an embodiment a combined thickness of the substrate 221 and the routing layer 223 may be a third thickness T₃. When the routing layer 223 is omitted, the third thickness T₃ may simply be the thickness of the substrate 221. In an embodiment, the third thickness T₃ may be approximately 1.5 mm or smaller, approximately 1.0 mm or smaller, approximately 700 μm or smaller, approximately 500 μm or smaller, or approximately 200 μm or smaller. Though, larger third thicknesses T₃ may also be used in some embodiments. As used herein, “approximately” may refer to a range of values within ten percent of the stated value. For example, approximately 500 μm may refer to a range between 450 μm and 550 μm. In an embodiment, a width of the layer 224 is greater than a width of the substrate 221.

In an embodiment, the device 220 may further comprise pads 222. The pads 222 may be electrically conductive material (e.g., comprising copper). The pads 222 may provide electrical coupling to the one or more electrically passive components on and/or in the substrate 221 and/or the routing layer 223. In the illustrated embodiment, the pads 222 extend up from the surface 242 of the routing layer 223. In other embodiments, the pads 222 may be embedded within the routing layer 223 or the substrate 221 (when the routing layer 223 is omitted).

Referring now to FIG. 2B, a cross-sectional illustration of a device 220 is shown, in accordance with an additional embodiment. In an embodiment, the device 220 may be similar to the device 220 in FIG. 2A, with the exception of the number of substrates 221 and routing layers 223 embedded in the layer 224. For example, the device 220 may comprise a first substrate 221A with a first routing layer 223A and a second substrate 221B with a second routing layer 223B. In an embodiment, the first pair 221A/223A and the second pair 221B/223B may be substantially similar to each other. Such a configuration may allow for easier assembly when multiple passive structures need to be embedded within a single core. While two substrate 221/routing layer 223 pairs are shown, it is to be appreciated that any number of pairs 221/223 may be included within the device 220.

Referring now to FIG. 2C, a cross-sectional illustration of a device 220 is shown, in accordance with an additional embodiment. The device 220 in FIG. 2C may be similar to the device 220 in FIG. 2B, with the exception of the structure of the substrates 221A and 221B. Instead of being similar to each other, the components may have different thicknesses. For example, a combined first thickness T₁ of the substrate 221A and the routing layer 223A may be greater than a combined second thickness T₂ of the substrate 221B and the routing layer 223B. Different component geometries may be the result of different types of passives being integrated into a single device 220. Despite having different structures, both the routing layers 223A and 223B may have top surfaces that are substantially coplanar with the top surface of the layer 224. This enables easier integration since the pads 222 will be at the same height. However, this may result in the bottom surfaces of the substrates 221A and 221B being different distances from the bottom surface of the layer 224.

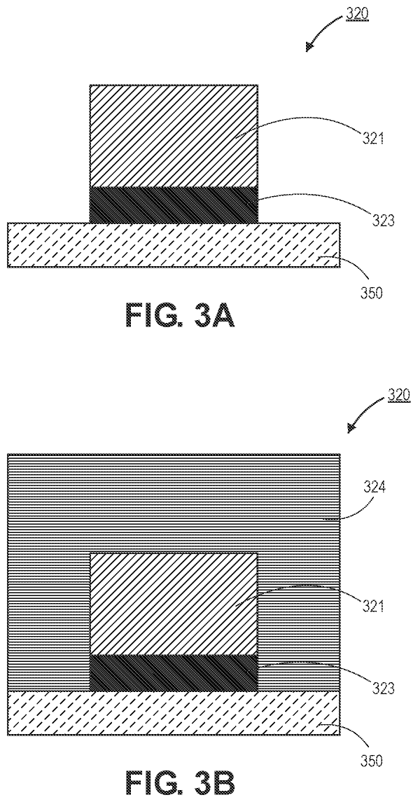

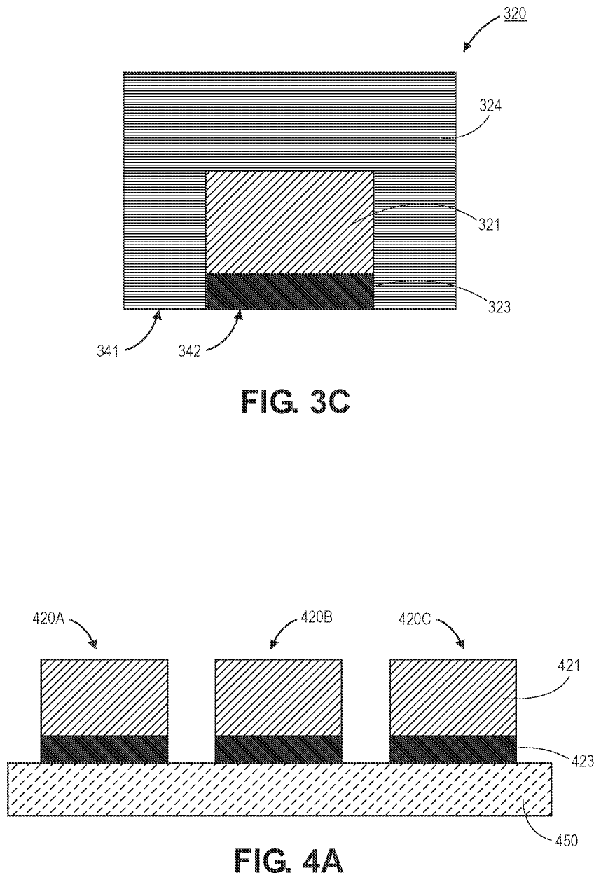

Referring now to FIGS. 3A-3C, a series of cross-sectional illustrations depicting a process for forming a device 320 is shown, in accordance with an embodiment. The device 320 may be considered as being individually fabricated. That is, a single substrate 321 and routing layer 323 are molded in the described process.

Referring now to FIG. 3A, a cross-sectional illustration of a device 320 at a stage of manufacture is shown, in accordance with an embodiment. In an embodiment, the device 320 is similar to any device described in greater detail herein. For example, the device 320 may include a substrate 321 with a routing layer 323. The device 320 may be attached to a carrier 350. Particularly, the routing layer 323 may be placed down onto the carrier 350. In some embodiments, the routing layer 323 is directly placed on the carrier 350. Other embodiments may include an adhesive or the like between the routing layer 323 and the carrier 350.

In an embodiment, the substrate 321 and the routing layer 323 may be similar to substrates and routing layers described in greater detail herein. For example, the substrate 321 or the substrate 321 and the routing layer 323 may house one or more electrically passive devices, such as an inductor, a capacitor, or a resistor. The carrier 350 may be a temporary support surface. The carrier 350 may comprise glass, ceramic, silicon, metal, or any other rigid material.

Referring now to FIG. 3B, a cross-sectional illustration of the device 320 at an advanced stage of manufacture is shown, in accordance with an embodiment. In an embodiment, a layer 324 is formed around the substrate 321 and the routing layer 323. The layer 324 may be formed with a molding process in some embodiments. Though, other deposition processes may also be used. The layer 324 may comprise any suitable molding material, such as, but not limited to, an epoxy or an organic dielectric material. In an embodiment the layer 324 may cover sidewalls of the routing layer 323 and the substrate 321. The layer 324 may also be disposed over the top surface of the substrate 321. That is, a thickness of the layer 324 may be greater than a combined thickness of the routing layer 323 and the substrate 321. The layer 324 may have a thickness that is substantially equal to a thickness of a core (not shown) in which the device 320 will be embedded. As such, any substrate 321 and routing layer 323 combination is rendered compatible and easy to integrate into thicker core substrates. As used herein, “substantially equal” may refer to two values that are within ten percent of each other. For example, a device with a thickness between 900 μm and 1,100 μm may be considered as being substantially equal in thickness to a core that is 1,000 μm.

Referring now to FIG. 3C, a cross-sectional illustration of the device 320 is shown, in accordance with an embodiment. In FIG. 3C, the carrier 350 has been removed in order to expose the bottom surface 341 of the layer 324 and the bottom surface 342 of the routing layer 323. The carrier 350 may be removed with any suitable process. Since the routing layer 323 and the layer 324 were placed on the same carrier 350 with a planar surface, the surface 341 may be substantially coplanar with the surface 342. After the carrier 350 is removed, pads (not shown) may be fabricated on the routing layer 342 similar to embodiments described in greater detail herein.

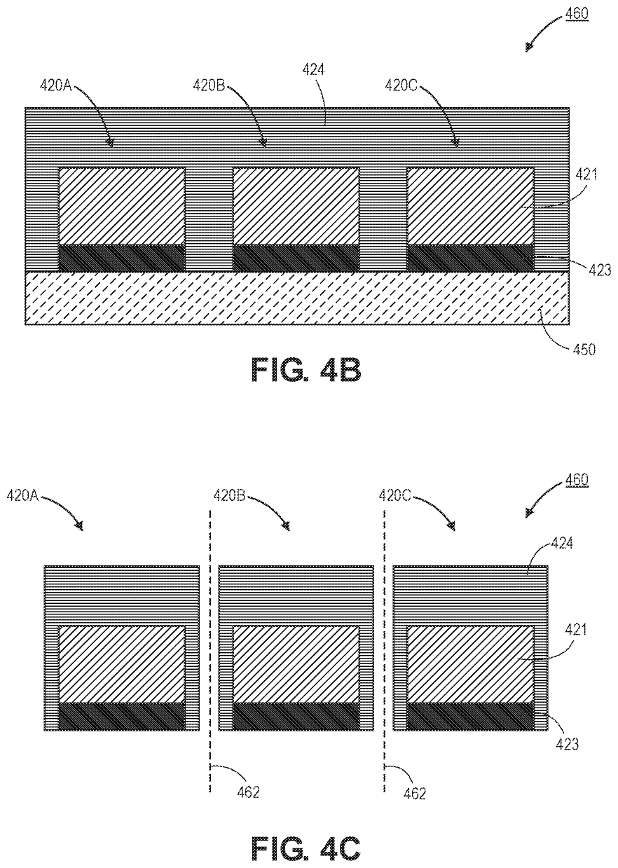

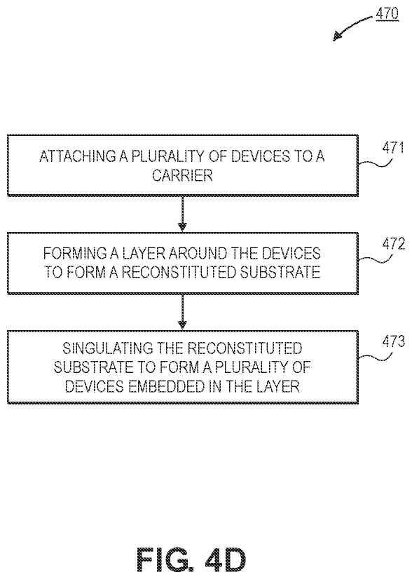

Referring now to FIGS. 4A-4C, a series of cross-sectional illustrations depicting an alternative process for forming devices 420 is shown, in accordance with an embodiment. As shown in FIGS. 4A-4C, a plurality of devices (e.g., devices 420A-420C) may be fabricated in parallel through the use of a reconstituted substrate 460 process.

Referring now to FIG. 4A, a cross-sectional illustration of a plurality of devices 420A-420C at a stage of manufacture is shown, in accordance with an embodiment. While three devices 420A-420C are shown in FIG. 4A, it is to be appreciated that any number (e.g., two or more) devices 420 may be used. The devices 420A-420C may be similar to any devices described in greater detail herein. For example, the devices 420A-420C may each include a substrate 421 with a routing layer 423. The devices 420A-420C may be attached to a carrier 450. Particularly, the routing layers 423 may be placed down onto the carrier 450. In some embodiments, the routing layers 423 are directly placed on the carrier 450. Other embodiments may include an adhesive or the like between the routing layers 423 and the carrier 450.

In an embodiment, the substrates 421 and the routing layers 423 may be similar to substrates and routing layers described in greater detail herein. For example, the substrates 421 or the substrates 421 and the routing layers 423 may house one or more electrically passive devices, such as an inductor, a capacitor, or a resistor. The carrier 450 may be a temporary support surface. The carrier 450 may comprise glass, ceramic, silicon, metal, or any other rigid material.

Referring now to FIG. 4B, a cross-sectional illustration of the devices 420A-420C at an advanced stage of manufacture is shown, in accordance with an embodiment. In an embodiment, a layer 424 is formed around the devices 420A-420C to form a reconstituted substrate 460. The layer 424 may be formed with a molding process in some embodiments. Though, other deposition processes may also be used in some embodiments. The layer 424 may comprise any suitable molding material, such as, but not limited to, an epoxy or an organic dielectric material. In an embodiment the layer 424 may cover sidewalls of the routing layers 423 and the substrates 421. The layer 424 may also be disposed over the top surface of the substrates 421. That is, a thickness of the layer 424 may be greater than a combined thickness of the routing layer 423 and the substrate 421 for each of the devices 420A-420C. The layer 424 may have a thickness that is substantially equal to a thickness of cores (not shown) in which the devices 420A-420C will be embedded. As such, any substrate 421 and routing layer 423 combination is rendered compatible and easy to integrate into thicker core substrates.

Referring now to FIG. 4C, a cross-sectional illustration of the reconstituted substrate 460 after singulation is shown, in accordance with an embodiment. After the carrier 450 is removed, the devices 420A-420C may be singulated along lines 462. The singulation process may include a physical process (e.g., sawing), a laser ablation process, an etching process, or the like. In some embodiments, pads (not shown) may be fabricated on the devices 420A-420C before singulation or after singulation.

Referring now to FIG. 4D, a process flow diagram depicting a process 470 for forming a plurality of devices with a reconstitution process is shown, in accordance with an embodiment. In an embodiment, the process 470 may begin with operation 471, which comprises attaching a plurality of devices to a carrier. In an embodiment, operation 471 may include structures and processes similar to those described herein with respect to FIG. 4A.

In an embodiment, the process 470 may continue with operation 472, which comprises forming a layer around the devices to form a reconstituted substrate, in accordance with an embodiment. In an embodiment, operation 472 may include structures and processes similar to those described herein with respect to FIG. 4B.

In an embodiment, the process 470 may continue with operation 473, which comprises singulating the reconstituted substrate to from a plurality of devices embedded in the layer. In an embodiment, operation 473 may include structures and processes similar to those described herein with respect to FIG. 4C.

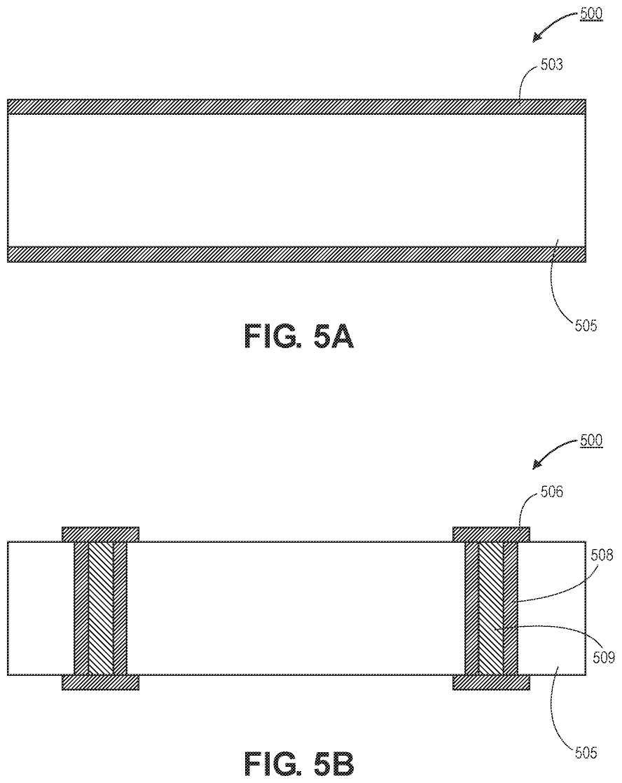

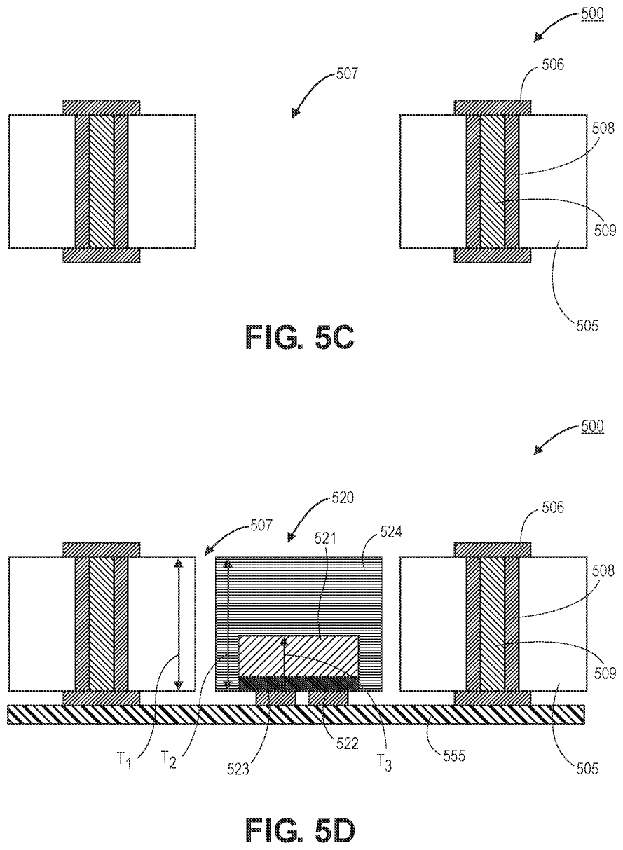

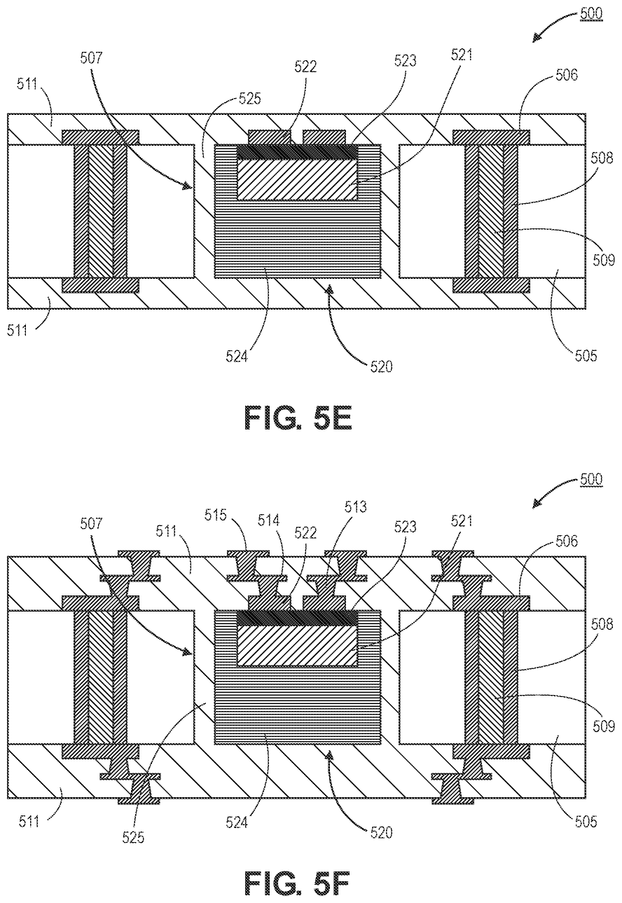

Referring now to FIGS. 5A-5F, a series of cross-sectional illustrations depicting a process for embedding a device 520 into a core 505 of a package substrate 500 is shown, in accordance with an embodiment.

Referring now to FIG. 5A, a cross-sectional illustration of a portion of a package substrate 500 is shown, in accordance with an embodiment. In an embodiment, the package substrate 500 may comprise a core 505. The core 505 may be an organic core or a glass core. The glass core 505 may be substantially all glass. The glass core 505 may be a solid mass comprising a glass material with an amorphous crystal structure where the solid glass core may also include various structures—such as vias, cavities, channels, or other features—that are filled with one or more other materials (e.g., metals, metal alloys, dielectric materials, etc.). As such, glass core 505 may be distinguished from, for example, the “prepreg” or “FR4” core of a Printed Circuit Board (PCB) substrate which typically comprises glass fibers embedded in a resinous organic material, such as an epoxy.

The glass core 505 may have any suitable dimensions. In a particular embodiment, the glass core 505 may have a thickness that is approximately 50 μm or greater. For example, the thickness of the glass core 505 may be between approximately 50 μm and approximately 1.4 mm. Though, smaller or larger thicknesses may also be used. The glass core 505 may have edge dimensions (e.g., length, width, etc.) that are approximately 10 mm or greater. For example, edge dimensions may be between approximately 10 mm to approximately 250 mm. Though, larger or smaller edge dimensions may also be used. More generally, the area dimensions of the glass core 505 (from an overhead plan view) may be between approximately 10 mm×10 mm and approximately 250 mm×250 mm. In an embodiment, the glass core 505 may have a first side that is perpendicular or orthogonal to a second side. In a more general embodiment, the glass core 505 may comprise a rectangular prism volume with sections (e.g., vias) removed and filled with other materials (e.g., metal, etc.).

The glass core 505 may comprise a single monolithic layer of glass. In other embodiments, the glass core 505 may comprise two or more discrete layers of glass that are stacked over each other. The discrete layers of glass may be provided in direct contact with each other, or the discrete layers of glass may be mechanically coupled to each other by an adhesive or the like. The discrete layers of glass in the glass core 505 may each have a thickness less than approximately 50 μm. For example, discrete layers of glass in the glass core 505 may have thicknesses between approximately 25 μm and approximately 50 μm. Though, discrete layers of glass may have larger or smaller thicknesses in some embodiments. As used herein, “approximately” may refer to a range of values within ten percent of the stated value. For example approximately 50 μm may refer to a range between 45 μm and 55 μm.

The glass core 505 may be any suitable glass formulation that has the necessary mechanical robustness and compatibility with semiconductor packaging manufacturing and assembly processes. For example, the glass core 505 may comprise aluminosilicate glass, borosilicate glass, alumino-borosilicate glass, silica, fused silica, or the like. In some embodiments, the glass core 505 may include one or more additives, such as, but not limited to, Al₂O₃, B₂O₃, MgO, CaO, SrO, BaO, SnO₂, Na₂O, K₂O, SrO, P₂O₃, ZrO₂, Li₂O, Ti, or Zn. More generally, the glass core 505 may comprise silicon and oxygen, as well as any one or more of aluminum, boron, magnesium, calcium, barium, tin, sodium, potassium, strontium, phosphorus, zirconium, lithium, titanium, or zinc. In an embodiment, the glass core 505 may comprise at least 23 percent silicon (by weight) and at least 26 percent oxygen (by weight). In some embodiments, the glass core 505 may further comprise at least 5 percent aluminum (by weight).

In an embodiment, the core 505 may comprise cladding 503 above and/or below the core 505. The cladding 503 may include an electrically conductive material, such as one comprising copper or the like. While shown with cladding 503, other embodiments may include a core 505 that omits one or both cladding 503 layers.

Referring now to FIG. 5B, a cross-sectional illustration of the portion of the package substrate 500 after vias 508 are formed is shown, in accordance with an embodiment. In an embodiment, the vias 508 may pass through at least a portion of a thickness of the core 505. The vias 508 may comprise electrically conductive material, such as material comprising copper. In the illustrated embodiment, the vias 508 are plated through hole vias 508 with an insulating plug 509. Though, in other embodiments the vias 508 may be fully filled with electrically conductive material. While shown with vertical sidewalls, it is to be appreciated that the vias 508 may have any shaped cross-section. For example, vias 508 may have sloped or tapered sidewalls in some embodiments. Pads 506 may be formed over and/or under the vias 508. In some embodiments, the pads 506 may be formed from cladding 503, which may otherwise be removed.

Referring now to FIG. 5C, a cross-sectional illustration of the portion of the package substrate 500 after a cavity 507 is formed in the core 505 is shown, in accordance with an embodiment. The cavity 507 may pass at least partially through a thickness of the core 505. For example, in FIG. 5C the cavity 507 passes entirely through a thickness of the core 505. In the illustrated embodiment, sidewalls of the cavity 507 are vertical. Though, the sidewalls of the cavity 507 may be sloped, non-vertical, non-planar, or the like.

Referring now to FIG. 5D, a cross-sectional illustration of the portion of the package substrate 500 after a device 520 is inserted into the cavity 507 is shown, in accordance with an embodiment. In an embodiment, a tape 555 or other carrier may be provided below the core 505. The tape 555 may span the cavity 507 in order to provide a support surface for the device 520. The device 520 may be placed on the tape 555 with a pick-and-place tool, manually, or with any other suitable process.

In an embodiment, the device 520 may be similar to any device described in greater detail herein. For example, the device 520 may comprise a substrate 521 with a routing layer 523. A layer 524 may at least partially embed the substrate 521 and the routing layer 523. In an embodiment, a width of layer 524 may be less than a width of the cavity 507. Pads 522 may also be provided on the routing layer 523.

In an embodiment, the core 505 may have a first thickness T₁, and the layer 524 may have a second thickness T₂ that is substantially equal to the first thickness T₁. A combined third thickness T₃ of the substrate 521 and the routing layer 523 may be smaller than the second thickness T₂. That is, the layer 524 of the device 520 modifies the overall thickness of the device 520 in order to match the thickness of the core 505 in order to simplify assembly processes.

Referring now to FIG. 5E, a cross-sectional illustration of the portion of the package substrate 500 after the cavity 507 is filled and buildup layers 511 are provided above and/or below the core 505 is shown, in accordance with an embodiment. In an embodiment, a fill layer 525 may surround the layer 524. The fill layer 525 may be a different material than the layer 524 in some embodiments. For example, the fill layer 525 may be an organic buildup film and the layer 524 may be an epoxy. Though, in other embodiments, the layer 524 and the fill layer 525 may be the same material or similar materials. In an embodiment, the buildup layers 511 may be the same material as the fill layer 525. For example, the fill layer 525 and the buildup layers 511 may be disposed onto the package substrate 500 with a single lamination process.

Referring now to FIG. 5E, a cross-sectional illustration of the portion of the package substrate 500 after routing is provided in the buildup layers 511 is shown, in accordance with an embodiment. For example, electrical routing (e.g., pads 515, vias 513, traces 514, etc.) may be formed on/within the buildup layers 511 using traditional processes, such as a semi-additive process (SAP).

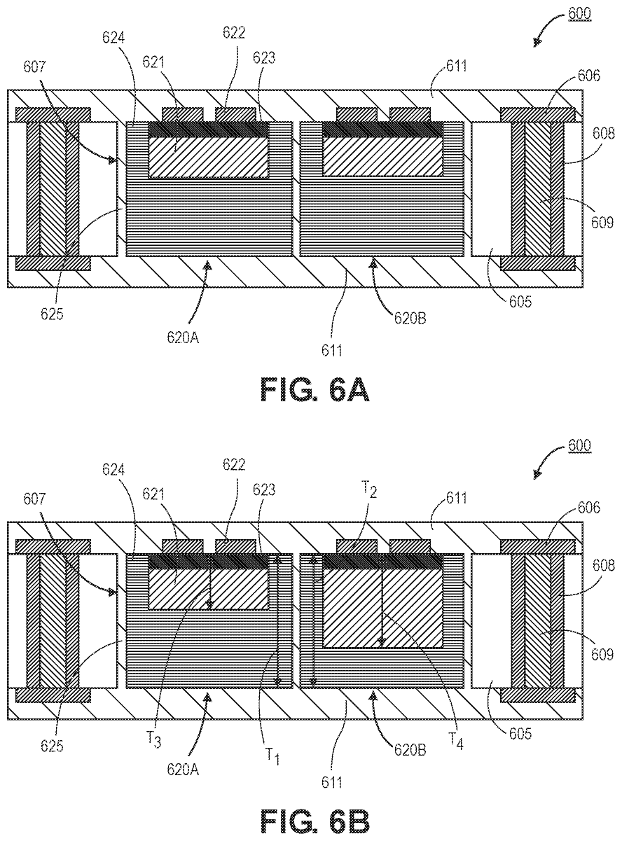

Referring now to FIG. 6A, a cross-sectional illustration of a portion of a package substrate 600 is shown, in accordance with an additional embodiment. In an embodiment, the package substrate 600 may comprise a core 605, such as a glass core 605 or an organic core 605. The core 605 may be similar to other cores described in greater detail herein. In an embodiment, vias 608 (with or without insulating plugs 609) may pass through the core 605. Pads 606 may be provided over and/or under the vias 608.

In an embodiment, a cavity 607 may be provided through a thickness of the core 605. A plurality of devices 620 may be embedded in the cavity 607 by a fill layer 625. For example, a first device 620A and a second device 620B are shown in FIG. 6A. The first device 620A and the second device 620B may be substantially similar to each other. For example, both may include a substrate 621 with a routing layer 623. Layers 624 may surround both devices 620A and 620B. In an embodiment, devices 620A and 620B may be similar to any devices described in greater detail herein. Additionally, pads 622 may be provided on each device 620. Buildup layers 611 may be provided over and/or under the core 605.

Referring now to FIG. 6B, a cross-sectional illustration of a portion of an electronic package 600 is shown, in accordance with an additional embodiment. The electronic package 600 in FIG. 6B may be similar to the electronic package 600 in FIG. 6A, with the exception of the structure of the first device 620A and the second device 620B. The first device 620A may include a first thickness T₁ that is substantially equal to a second thickness T₂ of the second device 620B. However, a combined third thickness T₃ of the substrate 621 and the routing layer 623 of the first device 620A may be different than a combined fourth thickness T₄ of the substrate 621 and the routing layer 624 of the second device 620B.

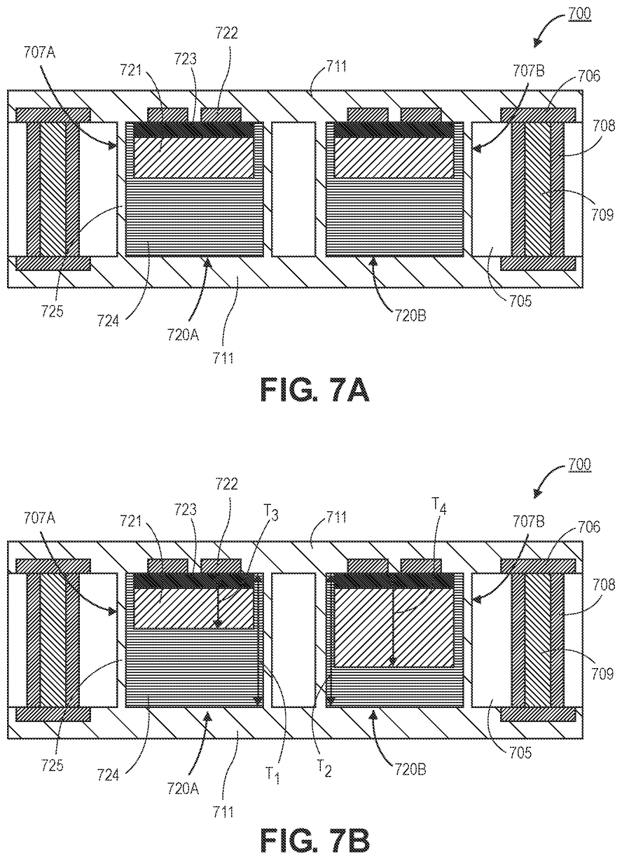

Referring now to FIG. 7A, a cross-sectional illustration of a portion of a package substrate 700 is shown, in accordance with an additional embodiment. In an embodiment, the package substrate 700 may comprise a core 705, such as a glass core 705 or an organic core 705. The core 705 may be similar to other cores described in greater detail herein. In an embodiment, vias 708 (with or without insulating plugs 709) may pass through the core 705. Pads 706 may be provided over and/or under the vias 708.

In an embodiment, a first cavity 707A and a second cavity 707B may be provided through a thickness of the core 705. A device 720A or 720B may be embedded in each of the cavities 707A and 707B by a fill layer 725. For example, a first device 720A may be provided in the first cavity 707A, and a second device 720B may be provided in the second cavity 707B. The first device 720A and the second device 720B may be substantially similar to each other. For example, both may include a substrate 721 with a routing layer 723. Layers 724 may surround both devices 720A and 720B. In an embodiment, devices 720A and 720B may be similar to any devices described in greater detail herein. Additionally, pads 722 may be provided on each device 720. Buildup layers 711 may be provided over and/or under the core 705.

Referring now to FIG. 7B, a cross-sectional illustration of a portion of an electronic package 700 is shown, in accordance with an additional embodiment. The electronic package 700 in FIG. 7B may be similar to the electronic package 700 in FIG. 7A, with the exception of the structure of the first device 720A and the second device 720B. The first device 720A may include a first thickness T₁ that is substantially equal to a second thickness T₂ of the second device 720B. However, a combined third thickness T₃ of the substrate 721 and the routing layer 723 of the first device 720A may be different than a combined fourth thickness T₄ of the substrate 721 and the routing layer 724 of the second device 720B.

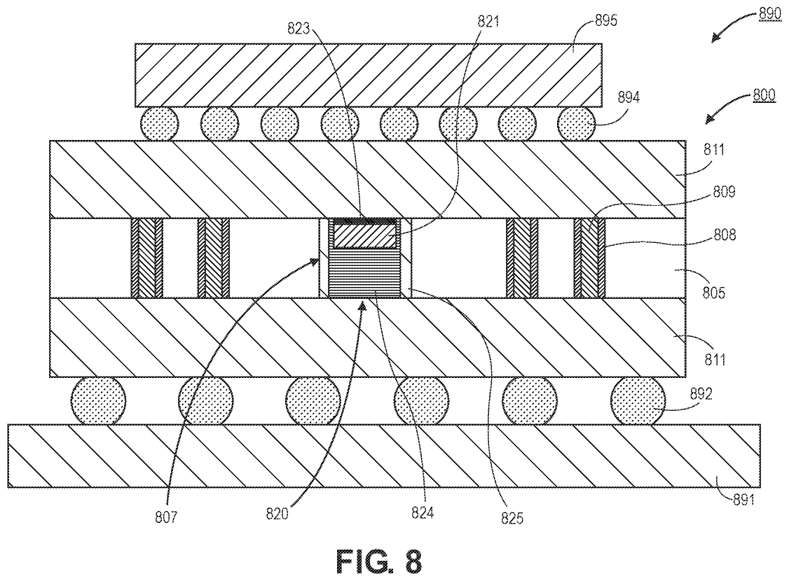

Referring now to FIG. 8, a cross-sectional illustration of an electronic system 890 is shown, in accordance with an embodiment. In an embodiment, the electronic system 890 comprises a board, such as a printed circuit board (PCB), a motherboard, or the like. In an embodiment, the board 890 is coupled to a package substrate 800 by interconnects 892. The interconnects 892 may be second level interconnects (SLIs), such as solder balls, sockets, pins, or the like.

In an embodiment, the package substrate 800 may be similar to any of the package substrates described herein. For example, the package substrate 800 may include a core 805 (e.g., a glass core 805 or an organic core 805) with buildup layers 811 above and below the core 805. The core 805 may comprise vias 808. In FIG. 8, the vias 808 are filled with an insulating plug 809. A cavity 807 may be provided through a thickness of the core 805. A device 820 may be embedded in a layer 825 that fills the cavity 807.

In an embodiment, the device 820 may be similar to any of the devices described in greater detail herein. For example, the device 820 may be a passive component such as one or more of an inductor, a capacitor, a resistor, or the like. The device 820 may have a total thickness that is substantially equal to a thickness of the core 805. In an embodiment, the device 820 may comprise a substrate 821 and a routing layer 823, both of which may be at least partially embedded by a layer 824.

In an embodiment, one or more dies 895 may be coupled to the package substrate 800 by interconnects 894. The interconnects 894 may comprise first level interconnects (FLIs), such as solder balls, copper bumps, hybrid bonding interfaces, or the like. The die 895 may be any type of die, such as a central processing unit (CPU), a graphics processing unit (GPU), an XPU, a communications die, a memory die, an application specific integrated circuit (ASIC), a field programmable gate array (FPGA), or the like. In an embodiment, the device 820 is electrically coupled to the one or more dies 895 in order to control and/or improve power delivery that is provided to the die 895.

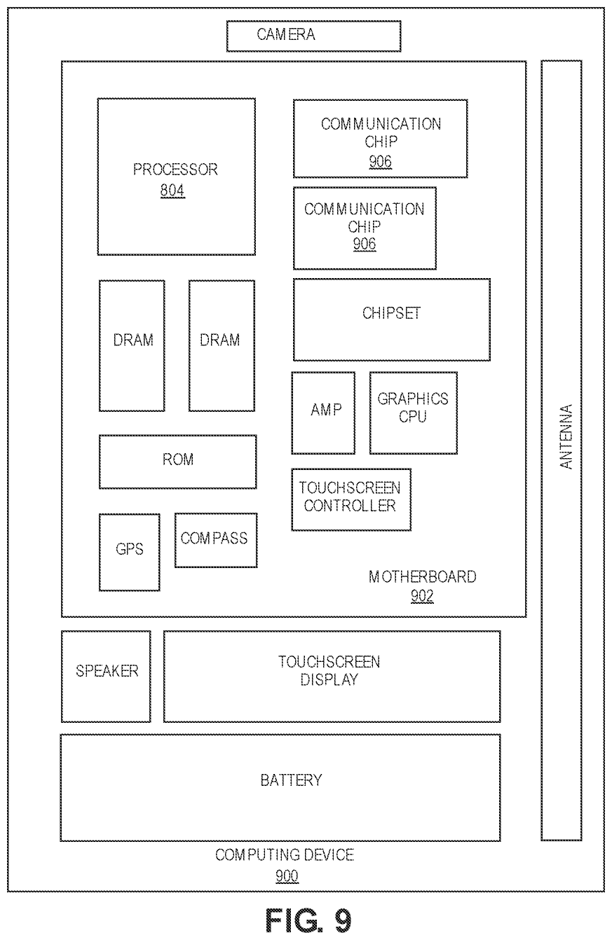

FIG. 9 illustrates a computing device 900 in accordance with one implementation of the disclosure. The computing device 900 houses a board 902. The board 902 may include a number of components, including but not limited to a processor 904 and at least one communication chip 906. The processor 904 is physically and electrically coupled to the board 902. In some implementations the at least one communication chip 906 is also physically and electrically coupled to the board 902. In further implementations, the communication chip 906 is part of the processor 904.

These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 906 enables wireless communications for the transfer of data to and from the computing device 900. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 906 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 900 may include a plurality of communication chips 906. For instance, a first communication chip 906 may be dedicated to shorter range wireless communications such as Wi-Fi and Bluetooth and a second communication chip 906 may be dedicated to longer range wireless communications such as GPS, EDGE, GPRS, CDMA, WiMAX, LTE, Ev-DO, and others.

The processor 904 of the computing device 900 includes an integrated circuit die packaged within the processor 904. In some implementations of the disclosure, the integrated circuit die of the processor may be part of an electronic package that includes a device with a substrate that is at least partially embedded in a mold layer that has a thickness that is substantially equal to a thickness of a core of the package substrate, in accordance with embodiments described herein. The term “processor” may refer to any device or portion of a device that processes electronic data from registers and/or memory to transform that electronic data into other electronic data that may be stored in registers and/or memory.

The communication chip 906 also includes an integrated circuit die packaged within the communication chip 906. In accordance with another implementation of the disclosure, the integrated circuit die of the communication chip may be part of an electronic package that includes a device with a substrate that is at least partially embedded in a mold layer that has a thickness that is substantially equal to a thickness of a core of the package substrate, in accordance with embodiments described herein.

In an embodiment, the computing device 900 may be part of any apparatus. For example, the computing device may be part of a personal computer, a server, a mobile device, a tablet, an automobile, or the like. That is, the computing device 900 is not limited to being used for any particular type of system, and the computing device 900 may be included in any apparatus that may benefit from computing functionality.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

Example 1: an apparatus, comprising: a substrate with a first width, wherein the substrate comprises a first surface, a second surface opposite from the first surface, and sidewall surfaces coupling the first surface to the second surface; and a layer with a second width that is greater than the first width, wherein the layer contacts the substrate and covers the sidewall surfaces and the first surface of the substrate.

Example 2: the apparatus of Example 1, wherein the substrate further comprises: a dielectric layer over the second surface, and wherein the layer covers sidewalls of the dielectric layer.

Example 3: the apparatus of Example 2, further comprising: a pad over the dielectric layer, wherein the pad is electrically conductive.

Example 4: the apparatus of Examples 1-3, wherein the substrate comprises a silicon substrate.

Example 5: the apparatus of Examples 1-4, wherein the layer comprises an epoxy or an organic dielectric material.

Example 6: the apparatus of Examples 1-5, wherein the substrate comprises one or more of an inductor, a capacitor, or a resistor.

Example 7: the apparatus of Examples 1-6, wherein a first thickness of the layer between a sidewall of the layer and the sidewall of the substrate is smaller than a second thickness of the layer between a bottom of the layer and the first surface of the substrate.

Example 8: the apparatus of Examples 1-7, wherein a thickness of the apparatus is approximately 1.0 mm or greater.

Example 9: the apparatus of Example 8, wherein a thickness of the substrate is up to approximately 700 μm.

Example 10: an apparatus, comprising: a core wherein the core has a first thickness; a cavity through a thickness of the core; a device in the cavity, wherein the device has a second thickness that is substantially equal to the first thickness, and wherein the device comprises: a first layer; and a passive component at least partially embedded in the first layer; and a second layer around the device within the cavity.

Example 11: the apparatus of Example 10, wherein the first layer is a different material than the second layer.

Example 12: the apparatus of Example 10 or Example 11, wherein the first layer is an epoxy, and wherein the second layer is an organic buildup film.

Example 13: the apparatus of Examples 10-12, wherein a surface of the first layer is substantially coplanar with a surface of the passive component.

Example 14: the apparatus of Examples 10-13, wherein the passive component comprises one or more of an inductor, a capacitor, or a resistor.

Example 15: the apparatus of Examples 10-14, wherein the core is an organic core or a glass core with a rectangular prism form factor.

Example 16: the apparatus of Examples 10-15, wherein the first layer covers a bottom surface of the passive component and sidewall surfaces of the passive component.

Example 17: an apparatus, comprising: a board; a package substrate coupled to the board, wherein the package substrate comprises: a core with a first thickness; and a passive component in a cavity through the core, wherein the passive component is embedded in an epoxy mold layer with a second thickness that is substantially equal to the first thickness, and wherein a width of the epoxy mold layer is smaller than a width of the cavity; and a die coupled to the package substrate.

Example 18: the apparatus of Example 17, wherein the passive component has a third thickness that is smaller than the first thickness.

Example 19: the apparatus of Example 17 or Example 18, wherein the passive component comprises one or more of an inductor, a capacitor, or a resistor.

Example 20: the apparatus of Examples 17-19, wherein the apparatus is part of a personal computer, a server, a mobile device, a tablet, or an automobile.

What is claimed is:

1. An apparatus, comprising:
a substrate with a first width, wherein the substrate comprises a first surface, a second surface opposite from the first surface, and sidewall surfaces coupling the first surface to the second surface; and
a layer with a second width that is greater than the first width, wherein the layer contacts the substrate and covers the sidewall surfaces and the first surface of the substrate.

2. The apparatus of claim 1, wherein the substrate further comprises:
a dielectric layer over the second surface, and wherein the layer covers sidewalls of the dielectric layer.

3. The apparatus of claim 2, further comprising:
a pad over the dielectric layer, wherein the pad is electrically conductive.

4. The apparatus of claim 1, wherein the substrate comprises a silicon substrate.

5. The apparatus of claim 1, wherein the layer comprises an epoxy or an organic dielectric material.

6. The apparatus of claim 1, wherein the substrate comprises one or more of an inductor, a capacitor, or a resistor.

7. The apparatus of claim 1, wherein a first thickness of the layer between a sidewall of the layer and the sidewall of the substrate is smaller than a second thickness of the layer between a bottom of the layer and the first surface of the substrate.

8. The apparatus of claim 1, wherein a thickness of the apparatus is approximately 1.0 mm or greater.

9. The apparatus of claim 8, wherein a thickness of the substrate is up to approximately 700 μm.

10. An apparatus, comprising:
a core wherein the core has a first thickness;
a cavity through a thickness of the core;
a device in the cavity, wherein the device has a second thickness that is substantially equal to the first thickness, and wherein the device comprises:
a first layer; and
a passive component at least partially embedded in the first layer; and
a second layer around the device within the cavity.

11. The apparatus of claim 10, wherein the first layer is a different material than the second layer.

12. The apparatus of claim 11, wherein the first layer is an epoxy, and wherein the second layer is an organic buildup film.

13. The apparatus of claim 10, wherein a surface of the first layer is substantially coplanar with a surface of the passive component.

14. The apparatus of claim 10, wherein the passive component comprises one or more of an inductor, a capacitor, or a resistor.

15. The apparatus of claim 10, wherein the core is an organic core or a glass core with a rectangular prism form factor.

16. The apparatus of claim 10, wherein the first layer covers a bottom surface of the passive component and sidewall surfaces of the passive component.

17. An apparatus, comprising:
a board;
a package substrate coupled to the board, wherein the package substrate comprises:
a core with a first thickness; and
a passive component in a cavity through the core, wherein the passive component is embedded in an epoxy mold layer with a second thickness that is substantially equal to the first thickness, and wherein a width of the epoxy mold layer is smaller than a width of the cavity; and
a die coupled to the package substrate.

18. The apparatus of claim 17, wherein the passive component has a third thickness that is smaller than the first thickness.

19. The apparatus of claim 17, wherein the passive component comprises one or more of an inductor, a capacitor, or a resistor.

20. The apparatus of claim 17, wherein the apparatus is part of a personal computer, a server, a mobile device, a tablet, or an automobile.
